(19) United States
(12) Patent Application Publication
(10) Pub. No.: US 2025/0351298 A1
(43) Pub. Date: Nov. 13, 2025

(54) Liquid Immersion Cooling Platform with Localized Cooling and Fluid Quality Detection

(71) Applicant: Modine LLC, Racine, WI (US)

(72) Inventor: Jimil M. Shah, Plano, TX (US)

(21) Appl. No.: 18/868,620

(22) PCT Filed: May 26, 2023
(86) PCT No.: PCT/US2023/023680

§ 371 Date: Nov. 22, 2024

Related U.S. Application Data
(60) Provisional application No. 63/346,061, filed on May 26, 2022.

(51) Int. Cl. H05K 7/20; G06F 1/20; G06K 7/10; G06K 19/077

(52) U.S. Cl. CPC H05K 7/20272; G06F 1/20; G06K 7/10366; G06K 19/07758; H05K 7/20236

(57) ABSTRACT

An immersion cooling system and methods for operating the system are described. The system can comprise a management system comprising a processor and a memory; a tank configured to hold a thermally conductive dielectric fluid; a computer component configured to be at least partially submerged within the dielectric fluid; and a fluid circulation system comprises a pump and a valve system. In one example embodiment, the management system is configured to instruct the pump and the valve system to draw the dielectric fluid from the tank, pass the dielectric fluid through a heat exchanger and deliver the dielectric fluid back to the tank.

### CROSS-REFERENCE TO RELATED APPLICATIONS

This application claims priority to U.S. Provisional Application No. 63/346,061 filed on May 26, 2022 the entire disclosure of which is hereby incorporated by reference.

This application is related to PCT publication WO2020/102090 filed Nov. 11, 2019 titled “Liquid Immersion Cooling Platform” owned by TMGCore, LLC which application is incorporated herein by reference.

### FIELD OF DISCLOSURE

The present disclosure relates to a liquid immersion cooling system adapted to house computing devices, for example, a liquid immersion cooling system including a control system for optimizing the temperature of the system.

### BACKGROUND

Traditional computing and/or server systems utilize air to cool the various components of these systems. Traditional liquid or water cooled computers utilize a flowing liquid to draw heat from computer components but avoid direct contact between the computer components and the liquid itself. The development of electrically non-conductive and/or dielectric fluid enables the use of immersion cooling in which computer components and other electronics may be submerged in a dielectric or electrically non-conductive liquid in order to draw heat directly from the component into the liquid. Immersion cooling can be used to reduce the total energy needed to cool computer components and may also reduce the amount of space and equipment necessary for adequate cooling.

### SUMMARY

The liquid immersion cooling systems are being implemented for various computing needs. As such, it is beneficial to describe an immersion cooling system which can be easily adapted for localized cooling and on demand filtration of the dielectric fluid.

Advantageously, the instant application pertains to an exemplary immersion cooling system and methods for operating the system. In one example embodiment, the system comprises a management system including a processor and a memory; a tank which can hold a thermally conductive dielectric fluid; a computer component which can be at least partially submerged within the dielectric fluid; and a fluid circulation system including a pump and a valve system. In this example, the management system can instruct the pump and the valve system to draw the dielectric fluid from the tank, pass the dielectric fluid through a heat exchanger and deliver the dielectric fluid back to the tank.

In one example, the system can include a sensor, and the management system can receive sensor data from the sensor and instruct the pump and the valve system based on the data. In one example, the sensor data is a fluid level in the tank. In one example, the management system can add the dielectric fluid to the tank when the sensor data drops below a threshold amount. In one example, the system includes a chassis, and the computer component is placed in the chassis. In one example, the system includes an RFID tag on the chassis or the computer component. In one example, the tank includes an RFID scanner configured to transmit or receive radio frequency waves and detect the RFID tag. In one example, the management system is configured to determine an inventory of a plurality of computer components in the tank based on data detected by the RFID scanner.

In one example, the chassis further comprise a fan or pump for circulating the dielectric fluid in the chassis. In one example, the sensor data incudes a tank temperature of the dielectric fluid in the tank, a chassis temperature of the dielectric fluid in a chassis, and a computer component temperature of the computer component. In one example, the management system can instruct the pump and the valve system to circulate the dielectric fluid based on the tank temperature, the chassis temperature and the computer component temperature. In one example, the fluid circulation system is configured to circulate the dielectric fluid in at least one of the following circuits: a first circuit in which the dielectric fluid can be drawn from the tank and delivered back to the tank; a second circuit in which the dielectric fluid can be drawn from the chassis and delivered back to the tank; and a third circuit in which the dielectric fluid can be drawn from a vicinity of the computer component and delivered back to the tank.

In one example, the fluid circulation system is configured to circulate the dielectric fluid in the first circuit, second circuit, and third circuit when the tank temperature exceeds a first threshold value. In one example, the fluid circulation system is configured to circulate the dielectric fluid in the second circuit when the chassis temperature exceeds a second threshold value. In one example, the fluid circulation system is configured to circulate the dielectric fluid in the third circuit when the computer component temperature exceeds a third threshold value.

In one example, the system includes an overflow pan extending below the tank. In one example, the overflow pan can collect any dielectric fluid overflowing from the tank. In one example, the system includes a fluid sensor (or a label sensor) in the overflow pan. In one example, the management sensor is configured to shut down the system when the fluid sensor detects an increase in the dielectric fluid level in the overflow tank below a threshold level.

In one example, the fluid circulation system further includes a plurality of filters and the valve system is configured to connect or disconnect each filter to the pump. In one example, the plurality of filters include a coarse filter, a particulate filter, or an adsorption filter. In one example, the system comprises a sensor system including a conductivity sensor, a resistivity sensor, a permittivity sensor, a relative humidity sensor, or a pressure transducer. In one example, the management system is configured to connect or disconnect at least one of the plurality of filters based on sensor data received from the sensor system. In one example, the management system can determine a pressure differential for at least one of the plurality of filters based on sensor data received from the sensor system. In one example, the management system can determine that the at least one of the plurality of filters malfunctions based on the pressure differential.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 shows a liquid immersion cooling system according to an example embodiment of the present disclosure.

FIG. 2 shows another liquid immersion cooling system according to an example embodiment of the present disclosure.

FIG. 3 shows yet another liquid immersion cooling system according to an example embodiment of the present disclosure.

FIG. 4 shows an exemplary computer component according to an example embodiment of the present disclosure.

FIG. 5 shows an exemplary heat transfer system according to an example embodiment.

FIG. 6 shows yet another liquid immersion cooling system according to an example embodiment of the present disclosure.

Throughout the drawings, the same reference numerals and characters, unless otherwise stated, are used to denote like features, elements, components, or portions of the illustrated embodiments. Moreover, while the present disclosure will now be described in detail with reference to the figures, it is done so in connection with the illustrative embodiments and is not limited by the particular embodiments illustrated in the figures and claims.

### DETAILED DESCRIPTION

Exemplary embodiments of the invention will now be described in order to illustrate various features of the invention. The embodiments described herein are not intended to be limiting as to the scope of the invention, but rather are intended to provide examples of the components, use, and operation of the invention.

### Immersion Cooling System

In one example embodiment, an immersion cooling system or a vessel can include a bath area, a sump area, a weir (e.g., in between the bath area and the sump area), a computing device, an optional robot, an optional pressure control system and a management system. In one example, the vessel can be a pressure controlled tank maintained at the atmospheric pressure (or within a range thereof) which can be cooled using a heat exchanger. In another example, the vessel is not pressure controlled. The computing device can be immersed in a dielectric fluid in the bath area of the vessel. The computing device can be connected to a network and perform various processing and computing tasks while immersed in the dielectric fluid (or “fluid”). The vessel can include a lid for accessing the bath area, the computing device and the sump area.

In one example, the heat exchanger can be a fluid-to-fluid heat exchanger. For example, the heat exchanger can receive a warm dielectric fluid from the vessel, and at the same time, receive a cool working medium. The heat exchanger can transfer the heat from the dielectric fluid to the working medium. In one example, the working medium can be transferred to a cooling device (which can be onsite or remote). In another example, the heat exchanger can be the cooling device, e.g., heatsink with or without a fan, refrigerator, chiller, etc. In this example, there may not be any need to cool a working medium because the heat exchanger can cool the dielectric fluid without the need for a working medium to be transferred to another facility. In one example, the heat exchanger can be placed in the tank. In another example, the heat exchanger can be placed outside the tank.

In one example, the robot can lift the computing device from the bath area of the vessel when the lid is open. The robot can place the lifted computing device in a magazine provided for storage of computing devices or on a vehicle. The robot can also lift a computing device from the magazine (or vehicle) and place it in the place of the computing device that was lifted from the bath area. The robot can be affixed to the vessel, the vehicle or another location. In this example embodiment, the vessel can be a two-phase cooling system. In other example embodiments, the vessel can be a single-phase cooling system, which may or may not have one or more of the above referenced components.

In one example embodiment, a pump can circulate the fluid within the vessel. For example, the pump can draw the dielectric fluid from the sump area, and transfer the fluid into the bath area. The fluid can then flow over the weir and return to the sump area. The pump can circulate the fluid through, e.g., a heat exchanger, a filter, various pipes and valves, before transferring the fluid to the bath area. The pump can circulate the fluid upon receiving an instruction from the management system. In one example, the pump can draw the fluid from the sump area and transfer it to the bath area. In another example, the pump can draw the fluid from the bath area and transfer it to the sump area.

In one example, the management system can receive data generated by sensors included in the liquid immersion cooling system. In one example, the management system can provide an alert, and/or take another appropriate action, e.g., based on a sensor reading, shut down the vessel. For example, the management system can adjust or control a heating element, fluid flow or temperature, pressure in the tank, fluid level, fluid purity and/or any number of other system parameters. Such adjustments are often based on one or more sensed parameters (e.g., detected by a sensor) of the liquid immersion cooling system. The sensed parameters can include, e.g., temperature (inside or outside the vessel), pressure, fluid level (in the bath area or the sump area), or power consumption of the system. In one example, the management system can instruct a pump and/or valve system of the tank to allow for dielectric fluid to be added to the tank when the fluid level falls below a threshold level. The dielectric fluid can come from an outside tank or reservoir.

In one example embodiment, the immersion cooling system can be a single-phase immersion cooling system. In this example, the dielectric fluid can remain in liquid form throughout the operation of the immersion cooling system. This may be different from a two-phase system in which the dielectric fluid can, e.g., evaporate and condense while cooling the computer components.

In one example, the immersion cooling system can include a tank that holds a volume of dielectric fluid. The tank can also be configured to hold computer components. A pump can draw the dielectric fluid from a sump area and transfer it to the tank. In this example embodiment, the pump can cause the fluid to flow over the weir into the sump area. In one example embodiment, the liquid immersion cooling system can include a bath area without a sump area. A pump can draw fluid from the bath area and transfer the fluid to, e.g., a heat exchanger, filter and/or other components. Subsequently, the fluid can be returned to the bath area, e.g., after losing heat in the heat exchanger or being cleaned in the filter. In this example embodiment, there may not be any need for the fluid to flow over a weir into the sump area, but in other embodiments, the immersion cooling system can include a weir.

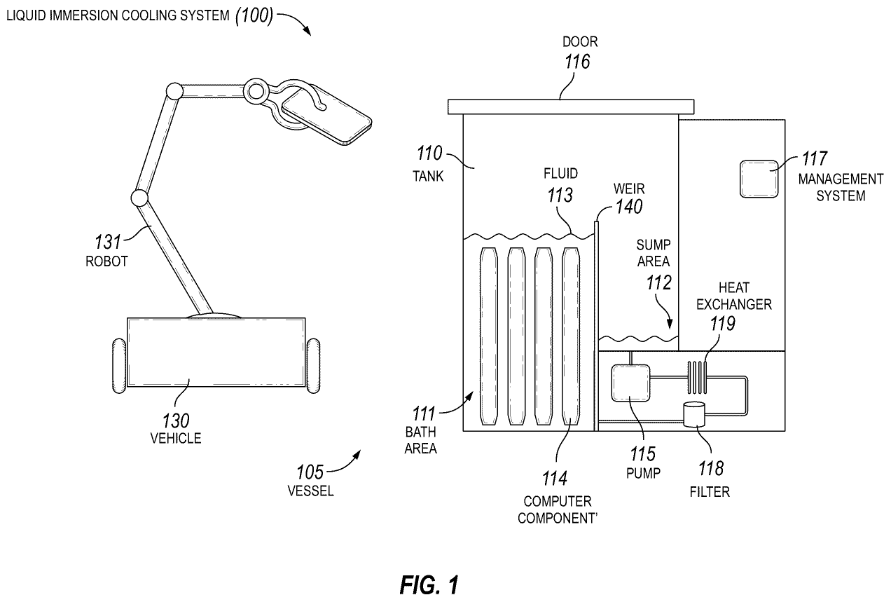

FIG. 1 shows a liquid immersion cooling system 100 according to an example embodiment of the present disclosure. In this example embodiment, the liquid immersion cooling system 100 can include a vessel 105 and a vehicle 130. The vessel 105 can comprise a tank 110, including a bath area 111, a sump area 112, a weir 140, a fluid 113, a computer component 114, a pump 115, a filter 118, a door 116, a management system 117, and a heat exchanger 119. The computer component 114 can be submersed in the fluid 113. The vehicle 130 can include a robot 131. The robot 131 can lift the computer component 114 when the door 116 is open and place the computer component 114 on the vehicle 130. The fluid 113 can flow over the weir 140 and accumulate in the sump area 112. In one example, the pump 115 can draw the fluid 113 from the sump area 112, and after passing it through the filter 118 and heat exchanger 119, transfer it to the bath area 111. One of ordinary skill in the art recognizes that an embodiment may include other components or arrangement of the components in the fluid transfer and circulation system, e.g., valves, pipes, etc., which may not have been displayed in the exemplary embodiment of FIG. 1.

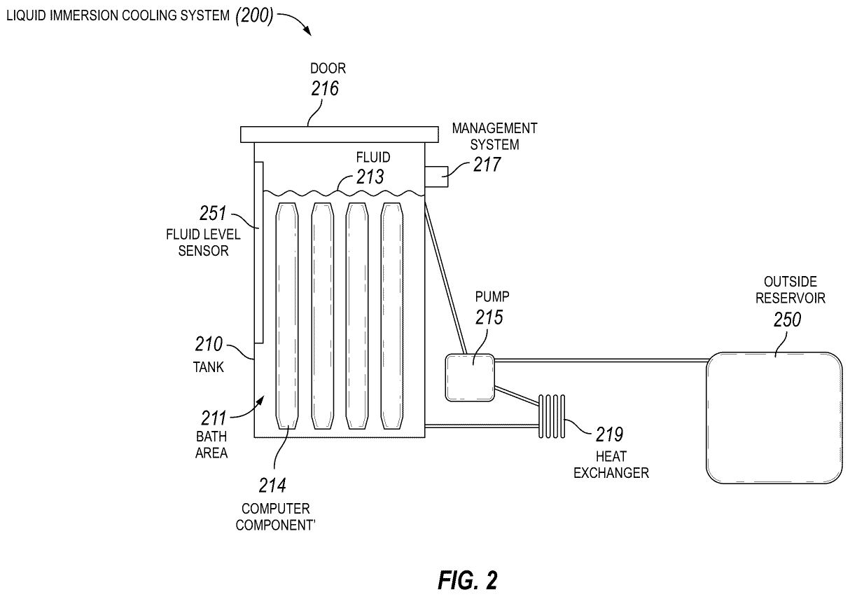

FIG. 2 shows a liquid immersion cooling system 200 according to an example embodiment of the present disclosure. In this example embodiment, the liquid immersion cooling system 200 can include a tank 210, including a bath area 211, a fluid 213, a computer component 214, a pump 215, a heat exchanger 219, a door 216, and a management system 217. The computer component 214 can be submersed in the fluid 213. In this example embodiment, the tank 210 may not be pressure controlled, though in some other example embodiments, the tank can be pressure controlled. In this example embodiment, the immersion cooling system can be a single-phase system, though in some other example embodiments, the immersion cooling system can be a two-phase system.

In this example embodiment, the pump 215 can receive an instruction from the management system 217 to draw fluid from the bath area 211 and deliver it to the heat exchanger, e.g., to maintain the temperature of the fluid 213 below a threshold temperature or to cool the computer component 214. In response, the pump 215 can draw the fluid 213 from the bath area 211 and pass the fluid 213 through the heat exchanger 219. Subsequently, the fluid 213 can be transferred to the bath area 211. One of ordinary skill in the art recognizes that other embodiments can include additional or fewer components to draw the fluid 213 from the bath area 211, and that these components can have a different arrangement in different embodiments, e.g., the heat exchanger can be placed before the pump 215.

In one example embodiment, the liquid immersion cooling system 200 can include a fluid level sensor 251 and an outside reservoir 250. In this example embodiment, the fluid level sensor can detect a fluid level within the tank 210 and convey the data to the management system 217. When the fluid level falls below a threshold level, the management system 217 can instruct the pump 215 to draw fluid from the outside reservoir 250. In one example, when the fluid level exceeds above a threshold level, the management system 217 can instruct the pump 215 to return the fluid to the outside reservoir 250. In one example, a chassis can include a fluid level sensor, and the management system can instruct the pump to draw fluid from the outside reservoir (or return the fluid to the outside reservoir) based on the data relayed by the sensor provided in the chassis.

### Localized Heat Dissipation

In one example embodiment, in addition to or instead of circulating the fluid in the bath area, various instruments can be provided to draw the fluid from the vicinity of one or more computer components (e.g., servers, chassis or CPUs) and transfer the fluid to a heat exchanger.

In one example, each computer component can be placed in a chassis and the chassis can include an input for receiving the dielectric fluid and an output for transferring the fluid outside of the chassis. In this example, the output of the chassis can be fluidly coupled to a heat exchanger or heatsink (e.g., through a hose or a pipe), and optionally, there can be a pump to draw the fluid from the chassis. In this example, the computer component can heat up the fluid within its vicinity or within the chassis, and the pump can draw the fluid. Because the fluid is drawn from an area close to the heat generating components, the pump can draw the warmest fluid and effectively cool the fluid.

In another example, each computer component (e.g., CPU) can include a component for drawing fluid (e.g., an input valve, a heatsink or a metal plate with liquid input and outlet). The component can be coupled to the heat exchanger using a pump and various pipes or hoses. Accordingly, the pump can draw the warm fluid from the vicinity of the computer component.

Yet in another example, the heat from the computer component can be transferred using heat pipes. In one example, a heat receiving component can be placed over or near the computer component (e.g., the heat receiving component can be thermodynamically coupled with the computer component). The heat receiving component can also be coupled to various heat pipes, which can transfer the heat from the computer component to a heat sink or radiator placed separate from the computer component. In this example, the heat from the computer component can be dissipated where the heatsink or radiator is.

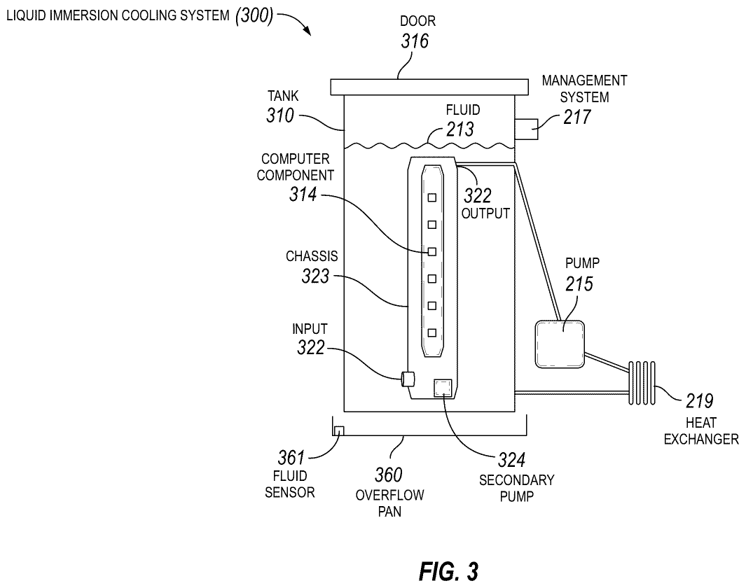

FIG. 3 shows a liquid immersion cooling system 300 according to an example embodiment of the present disclosure. In this example embodiment, the liquid immersion cooling system 300 can include a tank 310, a fluid 213, a door 316, a management system 217, a pump 215, and a heat exchanger 219. The tank 310 can further include a chassis 323 for housing a computer component 314. The chassis 323 can include an input 321 and an output 322. The fluid 213 can enter the chassis 323, e.g., through the input 321, and exist the chassis through the output 322. In this example, the output is connected to pump 215, e.g., using pipes. The pump 215 can draw fluid from the tank 310 and transfer it to the heat exchanger 219, to cool the fluid 213. Subsequently, the fluid can be transferred back into tank 310. In this example embodiment, the pump 215 can draw the fluid 213 from the vicinity of the computer component 314, thereby enabling cooling of the warmest fluid 213 in the tank 310.

In one example embodiment, a chassis can include one or more secondary pumps, fans, or any other means which can improve the flow (e.g., air stone bubbler without or without pump) for transferring the fluid in or outside of the chassis. In another example, a pump or fan can be installed on or within a vicinity of a computer component. For example, in the liquid immersion cooling system 300 of FIG. 3, the chassis 323 can include a secondary pump 324 to facilitate transfer and/or movement of the fluid 213 in the chassis 323. The pump 324 can draw fluid from the input 321 and/or push the fluid within the chassis 323 so that the fluid 213 transfers outside of the chassis 323 into the output 322. In this example, the pump 324 can faster transfer the heat generated by the computer component 314 outside the chassis 324.

In one example embodiment, a liquid immersion cooling system 300 can include an overflow pan 360. In the event there is an overflow of the fluid 213, the fluid can be directed to the overflow pan 360. The overflow pan 360 can prevent spillage of the fluid 213 over the floor. In one example, the overflow pan 360 can include a fluid sensor 361. The fluid sensor 361 can detect the presence of fluid 213 in the overflow pan 360. The fluid sensor 361 can transmit the data to the management system 217. In one example, the fluid sensor 361 can be a continuous float level sensor, a miniature continuous float level sensor, a miniature side mount 90 degree float switch, a high level float switch, a low level float switch, a combination of high level and low level float switch, an oil water interface, an adjustable float switch, a side mount, a multi-point float switch, visual a level indicator, a submersible suspendable float switch, an optical liquid level sensor, an oil level sensor, an oil pressure sensor, a conductivity sensor, or a point level sensor.

If the fluid sensor 361 detects fluid in the overflow pan 360, the management system 217 can transmit a message to a central server indicating possible leak at the liquid immersion cooling system 300. In one example, if the fluid sensor 361 detects fluid in the overflow pan 360 and the fluid level exceeds a threshold, the management system 217 can send a message indicating that the overflow pan 360 should be emptied or replaced. If the fluid level exceeds a threshold level or if the fluid level increases by more than a threshold level over a given period, the management system can detect an active leak. In this case, in one example, the management system can shut down the operation of the liquid immersion cooling system 300. In one embodiment, in the event the management system 217 detects an active leak, the management system 217 can instruct the pump 215 to return the fluid 213 to the reservoir 250.

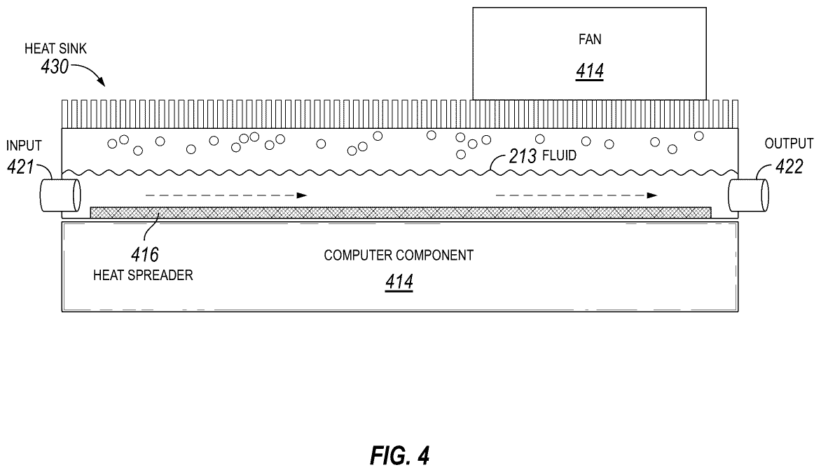

FIG. 4 shows an exemplary computer component 414 according to an example embodiment of the present disclosure. In this example embodiment, in addition to or instead of circulating the fluid in the tank, and/or in addition to or instead of circulating the fluid in the chassis, the fluid can be circulated in a component attached to the computer component 414. In this example embodiment, the component can be a heat sink 430, which can include an input 421 and an output 422. The fluid 213 can enter the heat sink 430 from the input 421 and exit the heat sink 430 through the output 422. The fluid 213 can be drawn from the output 422, e.g., by a pump and various pipes, and provided to a heat exchanger for cooling. In one example, the component attached to the computer component 414 can be an input valve or a housing with an input and an output. In one example embodiment, a fan 415 can be placed on the heat sink 430 to provide for additional cooling of the computer component 414. In one example, a heat spreader 416 (or a vapor chamber, cold plate, heat pipes or a heat sink) can be provided to transfer the heat from the computer component 414 to the fluid 213.

In one example, the fluid can be drawn from a vicinity of the computer component and cooled at a heat exchanger within the tank or chassis. For example, the tank can include a primary heat exchanger in the tank (or the primary heat exchanger can be outside the tank, but the secondary heat exchanger can be inside the tank). The pump can draw the fluid from the vicinity of the computer component and deliver it to the heat exchanger in the tank. The heat exchanger in the tank can be located, e.g., near the input point in the tank for cooled dielectric fluid.

In one example embodiment, a liquid immersion cooling system can circulate the fluid in various modes of operation. For example, in one mode of operation, a pump can circulate the fluid in the tank. In another optional mode, the pump can circulate the fluid in one or more chassis. In this mode, the fluid can circulate in a select number of chassis, but other chassis may be excluded from this fluid circulation. Yet in another optional mode, the pump can circulate the fluid in one or more components attached to one or more computer components. In this mode, the fluid can circulate in a select number of computer components (or components attached to the computer components), but other computer components may be excluded from this fluid circulation. In this example, the management system can instruct a valve system and/or pump to enable the operation of the liquid immersion cooling system in one or more of the foregoing modes of operation, e.g., switch the valve between a first circuit, a second circuit and or a third circuit, each circuit enabling fluid circulation for a specific chassis and/or computer component, and/or a plurality of chassis and/or computer components. In this example, the management system can circulate the fluid in selective group of individual chassis and/or computer components. In another example, the management system can instruct circulation of the fluid in all or a plurality of chassis and/or computer components. In one example, the management system can circulate the fluid in a combination of the first circuit, the second circuit and the third circuit.

In one example, the management system can receive sensor data indicating that one or more of the foregoing modes of operation must be activated. For examples, sensor data can include a temperature of the dielectric fluid in the tank, a temperature of one or more chassis and a temperature of one or more computer components. If the management system detects a temperature or a temperature increase beyond an acceptable threshold amount, the management system can instruct the pump and valve to activate one or more of the circuits. For example, if a temperature of a chassis increases beyond an acceptable temperature or a temperature of the surrounding chassis, the management system can activate the fluid circulation for that chassis to maintain the temperature of the chassis at an acceptable level. As another example, if the temperature of a computer component increases beyond an acceptable temperature or a temperature of the surrounding computer components, the management system can activate the fluid circulation for that computer component to maintain the temperature of the computer component at an acceptable level. In one example, if the temperature of the fluid in the tank increases beyond a first threshold amount, the management system can activate fluid circulation for the whole tank. If the temperature of the fluid in the tank still increases beyond a second threshold, the management system can activate the fluid circulation in one or more chassis and/or one or more computer components in addition to the fluid circulation in the tank.

In one example embodiment, the management system can activate a secondary pump inside a chassis or attached to a computer component based on a temperature of the chassis or the computer component. For example, if the temperature of the chassis or the computer component exceeds a threshold, the management system can activate one or more secondary pumps to facilitate quick heat transfer from the chassis or computer component.

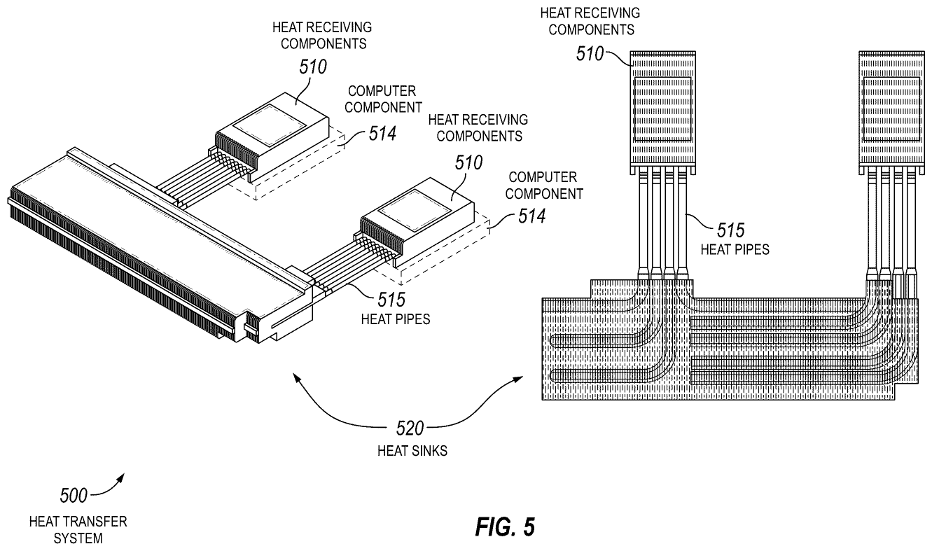

FIG. 5 shows an exemplary heat transfer system 500 according to an example embodiment. In this example embodiment, the heat transfer system 500 can include a heat receiving component 510, which can be thermodynamically coupled to the computer component 514. The heat receiving component 510 can be a thermal interface material, a heat spreader, a cold plate with or without mini-channel or micro-channel, a vapor chamber, or a combination of one or more of the foregoing.

The heat transfer system 500 can also include a heat pipe 515 and a heatsink 520 (or a radiator 520). In this example, the heat receiving component 510 can receive heat from the computer component 514, and using the heat pipes 515, transfer the heat to the heatsink 520. The heatsink 520 can be in the chassis housing the computer component 514. The heatsink 520 can also be located in the tank, e.g., close to the fluid entrance or close to fluid exit. Using the heat transfer system 500, the heat generated by the computer component 514 can be dissipated elsewhere in the tank.

In one example embodiment, a liquid immersion cooling system can include one or more of the above described localized heat dissipation systems. For example, a chassis can include a pump, a heat transfer system, and a radiator to dissipate the heat.

### RFID Tag

In one example embodiment, the management system and/or a secondary system can track the components installed or operating in an immersion cooling system. In this example embodiment, the management system and/or the secondary system can scan the components, e.g., using a robot or other scanners. In one example, each trackable component, e.g., chassis or computer component, can have an RFID tag. For example, the management system and/or the secondary system can transmit a radio frequency in the tank and determine which RFID tags are present in the tank. In another example, each trackable component can include a visual barcode, e.g., QR code, and the management system and/or the secondary system can scan the visual barcode. In one example, the RFID tag can be placed on the computer component. In another example, the RFID tag can be placed on the chassis.

In one example embodiment, the tank can include a robot, which can move within or outside the tank and can scan each trackable component in the tank. For example, the robot can be a gantry robot or a robotic arm on a vehicle, which can move close to each trackable component and scan the component, e.g., by transmitting or receiving RF signals. Subsequently, the robot can transmit the data to the management system. In another example, the tank can include one or more scanners within the tank, e.g., each scanner can be located within a distance of another scanner. Each scanner can be configured to detect the trackable components within its scanning range.

In one example embodiment, the management system can receive data about a temperature of a chassis and/or computer component. If the chassis or computer component operates above a threshold temperature for a longer than a threshold period, the management system can infer that the chassis and/or the computer component requires service and/or replacement. In one example, the management system can infer that the chassis and/or the computer component requires service, e.g., if the chassis and/or the computer component operates below a threshold temperature, e.g., significantly below the operating temperature for the chassis and/or the computer component.

When the management system infers that a chassis and/or a computer component requires service, the management system can transmit a message to a central server for sending, e.g., a service robot. The management system can also transmit a message even if the chassis or computer component is not broken, e.g., when monthly or annual service is required. In this example embodiment, a service robot can approach the tank and communicate with the management system, e.g., directly or through the central server. The management system can provide data about the chassis and/or the computer component which requires service. The data can include the identification information (e.g., RFID tag) for the chassis or computer component and/or its location within the tank. In this example, the service robot can locate the broken component, e.g., using the identification or location information or by scanning the RFID tag of the component. The service robot can further be configured to lift the component from the tank.

### Fluid Filter

In one example embodiment, the liquid immersion cooling system can include one or more filters. The liquid immersion cooling system can also include one or more sensors (e.g., a sensor system including a plurality of sensors), which can detect whether filtration of the fluid is desired. In one example embodiment, each filter can be connected to or disconnected from the fluid line on demand by the management system. For example, each filter can be connected or disconnected based on a sensor reading. On demand filtration can provide several benefits. For example, when filters can be connected on demand, there is no need for the pump to pass the dielectric liquid through all the filters all the time. This selective connection of filters can save electricity because lower pressure is needed to circulate the fluid in the fluid circulation system. As another example, because each filter can be isolated, the pressure differential for each filter, the temperature of the filter and/or the filter's conductivity can be detected over time. This information can indicate whether the filter has lost its efficacy and therefore requires changing or service.

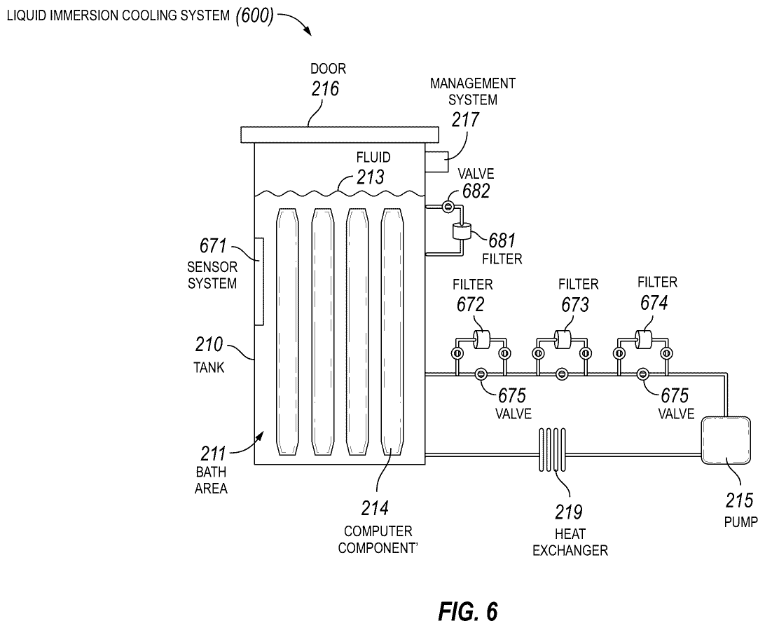

FIG. 6 shows a liquid immersion cooling system 600 according to an example embodiment of the present disclosure. In this example embodiment, the liquid immersion cooling system 600 can include a sensor system 671, a plurality of filters 672-674, and a plurality of valves 675. During the operation of the system 600, the sensor system 671 can detect a condition which may require filtration of the fluid. For example, the sensor system 671 can detect particulates, whiskers, plasticizers, or moisture in the fluid 213. The sensor system 671 can communicate this information to the management system 217. In this example, the management system 217 can determine that one or more of the filters 672-674 can be activated or connected to remedy the condition detected by the sensor system 671. Thus, the management system 217 can instruct one or more of the valves 675 to open or close to direct the fluid 213 in the appropriate direction. In one example, the filters can include coarse filter, particulate filter, adsorption filter and/or water separator. In one example, the sensor system can include a conductivity sensor, a resistivity sensor, a permittivity sensor, a relative humidity sensor, and/or a pressure transducer.

In one example, when an adsorption filter (e.g., a carbon or aluminum filter) is operating sub-optimally, the filter's conductivity can be reduced. In this example, a conductivity sensor can be used to determine that the filter is requires service and/or replacement. In one example embodiment, a sensor system can be provided in the tank. The sensor system can be, e.g., a Raman spectrometer, a humidity sensor, and/or a conductivity sensor. The sensor system in this example can trigger filtration in the tank.

In the example embodiment of FIG. 6, the management system 217 can isolate each of the filters 672-674. In one example, the management system 217 can record the pressure differential and/or temperature of each filter over time. For example, as each filter is installed, the management system can record the pressure differential and/or temperature of the filter during the filter's operation. If the pressure differential and/or temperature of a filter changes more than a threshold amount, this can indicate that the filter does not operate as intended, e.g., the filter malfunctions. In this example embodiment, the management system can transmit a message to a central server that the filter has to be changed and/or service is required. In certain embodiments, if a particular filter malfunctions, the management system can stop the operation of the system to prevent damages to the computer component 214. In one example embodiment, if the pressure differential and/or temperature of a filter changes less than another threshold amount, this can indicate that the filter does not operate as intended.

In one example embodiment, the liquid immersion cooling system can include one or more filtration circuits. Each filtration circuit can draw fluid from the tank and circulate the fluid through one or more filters and/or other components, e.g., a pump, a heat exchanger, a sensor, etc. In the example embodiment of FIG. 6, there are two exemplary filtration circuits. One exemplary filtration circuit can include filters 672-674. This filtration circuit can also include the pump 215, the heat exchanger 219, and various sensors such as temperature and pressure sensors. The second filtration circuit can include a filter 681. In this example embodiment, the second filtration circuit can also include a valve 682, various pipes, a pump and a sensor (not displayed in FIG. 6). The management system 217 can activate each filtration circuit, separately and/or combined with other filters. For example, the management system 217 can instruct the pump of the second circuit to draw the fluid from the tank, e.g., when one of the filters 672-674 of the first circuit fails to operate properly or when another condition is satisfied. By using multiple filtration circuits, the liquid immersion cooling system can provide redundancy. For example, even if a filter fails, in one example, the system can still operate while the failed filter is being replaced because the filters are provided on separate circuits.

In the preceding specification, various embodiments have been described with references to the accompanying drawings. It will, however, be evident that various modifications and changes may be made thereto, and additional embodiments may be implemented, without departing from the broader scope of the invention as set forth in the claims that follow. The specification and drawings are accordingly to be regarded as an illustrative rather than restrictive sense.

What is claimed is:

1. A system comprising:
a management system comprising a processor and a memory;
a tank configured to hold a thermally conductive dielectric fluid;
a computer component configured to be at least partially submerged within the dielectric fluid; and
a fluid circulation system comprises a pump and a valve system;
wherein the management system is configured to instruct the pump and the valve system to draw the dielectric fluid from the tank, pass the dielectric fluid through a heat exchanger and deliver the dielectric fluid back to the tank.

2. The system of claim 1, further comprising a sensor, wherein the management system is configured to receive sensor data from the sensor and instruct the pump and the valve system based on the data.

3. The system of claim 2, wherein the sensor data is a fluid level in the tank.

4. The system of claim 3, wherein the management system is configured to add the dielectric fluid to the tank when the sensor data drops below a threshold amount.

5. The system of claim 2, further comprising a chassis, wherein the computer component is placed in the chassis.

6. The system of claim 5, further comprising an RFID tag on the chassis or the computer component.

7. The system of claim 6, wherein the tank includes an RFID scanner configured to transmit or receive radio frequency waves and detect the RFID tag.

8. The system of claim 7, wherein the management system is configured to determine an inventory of a plurality of computer components in the tank based on data detected by the RFID scanner.

9. The system of claim 5, wherein the chassis further comprise a heat transfer system comprising a heat receiving component, a heat pipe and a heatsink, wherein the heat receiving component is thermodynamically coupled to the computer component and is configured to transfer heat from the computer component to the heatsink using the heat pipe.

10. The system of claim 5, wherein the chassis further comprise a fan or pump for circulating the dielectric fluid in the chassis.

11. The system of claim 5, wherein the sensor data incudes a tank temperature of the dielectric fluid in the tank, a chassis temperature of the dielectric fluid in a chassis, and a computer component temperature of the computer component.

12. The system of claim 11, wherein the management system is configured to instruct the pump and the valve system to circulate the dielectric fluid based on the tank temperature, the chassis temperature and the computer component temperature.

13. The system of claim 11, wherein the fluid circulation system is configured to circulate the dielectric fluid in at least one of the following circuits:
a first circuit in which the dielectric fluid is drawn from the tank and delivered back to the tank;
a second circuit in which the dielectric fluid is drawn from the chassis and delivered back to the tank; and
a third circuit in which the dielectric fluid is drawn from a vicinity of the computer component and delivered back to the tank.

14. The system of claim 13, wherein the fluid circulation system is configured to circulate the dielectric fluid in the first circuit, second circuit, and third circuit when the tank temperature exceeds a first threshold value.

15. The system of claim 13, wherein the fluid circulation system is configured to circulate the dielectric fluid in the second circuit when the chassis temperature exceeds a second threshold value.

16. The system of claim 13, wherein the fluid circulation system is configured to circulate the dielectric fluid in the third circuit when the computer component temperature exceeds a third threshold value.

17. The system of claim 1, further comprising an overflow pan extending below the tank.

18. The system of claim 17, wherein the overflow pan is configured to collect any dielectric fluid overflowing from the tank.

19. The system of claim 17, further comprising a fluid sensor in the overflow pan.

20. The system of claim 19, wherein the management sensor is configured to shut down the system when the fluid sensor detects an increase in the dielectric fluid level in the overflow tank below a threshold level.

21. The system of claim 1, wherein the fluid circulation system further includes a plurality of filters and the valve system is configured to connect or disconnect each filter to the pump.

22. The system of claim 21, wherein the plurality of filters comprise a coarse filter, a particulate filter, or an adsorption filter.

23. The system of claim 21, further comprising a sensor system including a conductivity sensor, a resistivity sensor, a permittivity sensor, a relative humidity sensor, or a pressure transducer.

24. The system of claim 23, wherein the management system is configured to connect or disconnect at least one of the plurality of filters based on sensor data received from the sensor system.

25. The system of claim 23, wherein the management system is configured to determine a pressure differential for at least one of the plurality of filters based on sensor data received from the sensor system.

26. The system of claim 25, wherein the management system is configured to determine that the at least one of the plurality of filters malfunctions based on the pressure differential.

27. The system of claim 23, wherein the management system is configured to determine a conductivity across at least one of the plurality of filters based on sensor data received from the sensor system.
